(19) United States
(12) Patent Application Publication
(10) Pub. No.: US 2002/0065974 A1
(43) Pub. Date: May 30, 2002

(54) Measurement-based management of relational databases

(76) Inventor: Chad Grey Thompson, Kuna, ID (US)

Correspondence Address: Fred G. Pruner, Jr., TROP, PRUNER & HU, P.C., Suite 100, 8554 Katy Freeway, Houston, TX, 77024, US

(21) Appl. No.: 09/727,116

(22) Filed: Nov. 30, 2000

(51) Int. Cl. G11C 5/00

(52) U.S. Cl. 711/1

(57) ABSTRACT

A technique includes providing a mapping table that indicates different rules for purging and/or archiving different database tables. Each rule is associated with a different database table. The rules are applied to purge and/or archive data from the different database tables.

### BACKGROUND

The invention relates to measurement-based management of relational databases.

For purposes of facilitating the storage and retrieval of large amounts of data, the data may be stored in a database. One type of database is a relational database, a database in which the data is stored as relations in rows and columns. Each column of the relational database is identified by its column name, and the ordering of the rows of data is immaterial.

The data in the relational database is further organized into tables. For example, a company may have one table that is associated with employee addresses, one table that is associated with employee compensation, etc. As a further example, the employee address table may include such columns as an employee identification column and an internal mail stop address column. Each row of the table may be associated with a different employee.

Software that manages a relational database typically does not have a mechanism in place to purge and/or archive data from the various tables of the database. In this manner, as more information is inserted into these tables, the tables grow in size, thereby increasing the size of the database. Unfortunately, as the database grows in size, the rate at which data may be retrieved from and stored in the database decreases.

Thus, there is a continuing need for an arrangement that addresses one or more of the problems that are stated above.

### SUMMARY

In an embodiment of the invention, a technique includes providing a mapping table that indicates different rules for archiving different database tables. Each rule is associated with a different database table, and the rules are applied to archive the data from the different database tables.

In another embodiment of the invention, a technique includes providing a mapping table that indicates different rules for purging different database tables. Each rule is associated with a different database table, and the rules are applied to purge the data from the different database tables.

Other features and advantages of the invention will become apparent from the following description drawing and claims.

### BRIEF DESCRIPTION OF THE DRAWING

FIG. 1 is a schematic diagram of a system according to an embodiment of the invention.

FIG. 2 is a flow diagram depicting a technique to create a mapping table used to purge and/or archive data of a relational database of FIG. 1 according to an embodiment of the invention.

FIG. 3 is an illustration of a mapping table according to an embodiment of the invention.

FIG. 4 is a schematic diagram of a computer system according to an embodiment of the invention.

FIG. 5 is a flow diagram depicting a technique to manage a database according to an embodiment of the invention.

### DETAILED DESCRIPTION

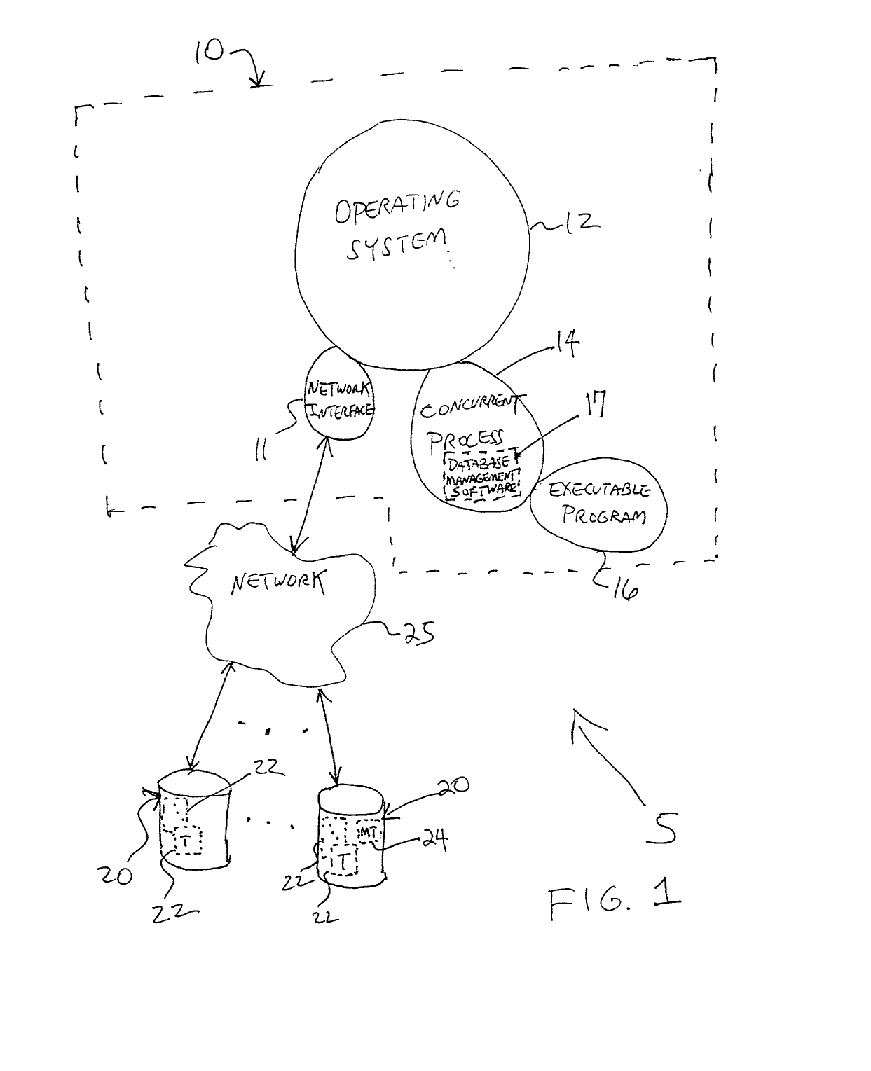

Referring to FIG. 1, an embodiment 5 of a system in accordance with the invention includes a computer system 10, a network 25 and relational databases 20. The databases 20 store tables, such as tables 22 and a mapping table 24 (described below), and the computer system 10 may access the relational databases 20 (via the network 25) for purposes of storing data in and retrieving data from these tables. In this manner, the computer system 10 may include an operating system 12 that creates a concurrent process 14 in which the resources for database management software 17 (software made by Oracle®, for example) may reside. The computer system's execution of the database management software 17 may cause a network interface layer 11 (of the computer system 10) to communicate with the databases 20 to retrieve and store data in the tables 22 over time.

The continuing storage of data in the tables 22 by the computer system 10 and possibly over computer systems may cause the tables 22 to expand in size over time, and the expanded sizes of the databases 20, in turn, may slow down accesses to the databases 20. However, for purposes of managing the sizes of the databases 20, the computer system 10 executes a program 16 (a script, for example) from the platform that is provided by database management software 17. As described below, the execution of the program 16 causes the computer system 10 to select, according to a predefined set of rules, the particular rows of data from the databases 20 that should be purged and/or archived. Therefore, the computer system 10, through the execution of the program 16, continually removes data (from the databases 20) that may be outdated or otherwise invaluable and thus, minimizes the sizes of the databases 20. As described below, the selection of the data to be purged and/or archived is controlled by the mapping table 24, a table that may be stored in one of the databases 20 (for example) and is capable of indicating different rules (for the different tables 22) that trigger the archiving and/or purging of rows of data from the tables 22.

In the context of this application, to archive a row of data means to copy the row of data from one database to an archive medium, such as a specific archive database, a tape backup, a compressed file or any other electronic medium. To purge a row means to remove, or delete, the row from the database.

The tables 22 may be associated with different functions and may be structured differently. Thus, each table 22 may have different archiving and purging needs. For example, one of the tables 22 may be associated with payroll data that needs to be stored for seven years. Continuing this example, it may be desired that the rows (of this table 22) that are over seven years old are purged. As another example, another one of the tables 22 may be associated with sales order data, and it may be desired to archive and then purge each row (of this table) that is over one year old. Criteria other than time may also be used as rules to govern when a particular row should be purged and/or archived. For example, other measurements, such as the size of a row or the number of rows of a particular table, may govern when the rows of a particular table 22 or the entire table 22 itself should be purged and/or archived.

Due to the different purging and archiving needs of the different tables 22, conventional purging and archiving techniques for relational databases involve the manual traversing of the rows of each table 22 to target the rows to be purged and/or archived or involves the creation of a specific script for each table detailing the actions to be performed on that table. Thus, these techniques are time consuming and typically have to be performed by a database administrator with input from other technical and functional personnel.

However, unlike conventional systems, the system 5 includes the mapping table 24, a reusable structure that encapsulates the logic used for purging and/or archiving data in the different tables 22. The mapping table 24 provides flexibility in establishing the rule for each table 22, may be used by a periodically called routine used for purposes of purging and/or archiving, may reduce the time needed for purging/and or archiving functions and may reduce the number of errors that occur as compared with manually performing these functions.

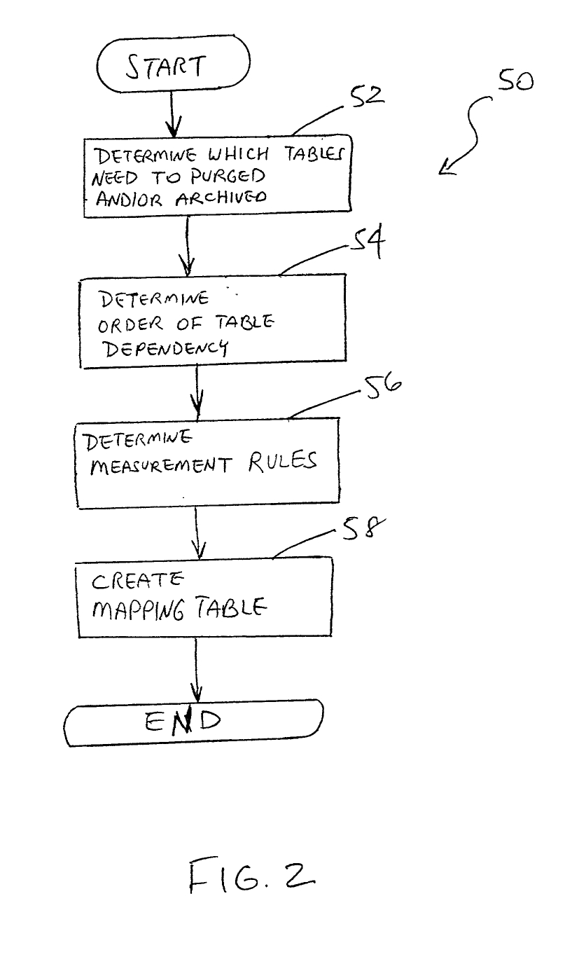

For purposes of constructing the mapping table 24, a technique 50 that is depicted in FIG. 2 may be used. The technique 50 includes determining (block 52) which tables 22 need to be purged and/or archived to some extent. In this manner, many tables 22 may just store lookup values for other tables or applications, static information, or data that otherwise cannot be purged due to technical or functional reasons.

Next, an order of table dependency is determined, as depicted in block 54. This may include determining the locking ladder of the table foreign keys and dependencies. In this manner, table relations may get very complicated, as some tables 22 may depend on other tables 22 that, in turn, depend on other tables 22. For example, if a particular table A has the highest hierarchical order, table B has the next highest hierarchical order and table C has the lowest hierarchical order of the three, then the data must be purged in a specific order (in reverse hierarchical order, for example). As an example, for the scenario described above, rows from table C may be purged before rows from table B, and rows from table B may be purged before rows from table A.

After the order of table dependency is determined, the rules that govern the purging and/or archiving for the rows of the various tables 22 are subsequently determined, as depicted in block 56. Thus, for each table 22, a rule is chosen that governs when the measurement of a particular property of a row designates the row for the purging and/or archiving functions. In this manner, the rules may be based on a certain creation date field in each table 22, a total number of rows of the table 22, a sequence number of the rows, etc.

As an example, a particular table 22 may have a column that contains values that indicate the creation date for each row of the table 22. Continuing the example, for a particular table 22, the mapping table 24 may indicate a rule to purge and archive the rows (in the table 22) that are older than 90 days. As another example, the mapping table 24 may indicate a rule for another table 22 to just purge (and not archive) rows (in that table 22) that are older than 30 days. As yet another example, the mapping table 24 may indicate a rule for another table 22 to never purge data from that table 22. After the ordering and creation of the rules, the technique 50 includes creating (block 58) the mapping table 24 using the rules and priorities described above.

More specifically, in some embodiments of the invention, the mapping table 24 includes rows, each of which is associated with a particular table 22. The columns of the table 22 indicate the functions and measurement rules for the associated table 22 that were created using the technique 50 that is described above.

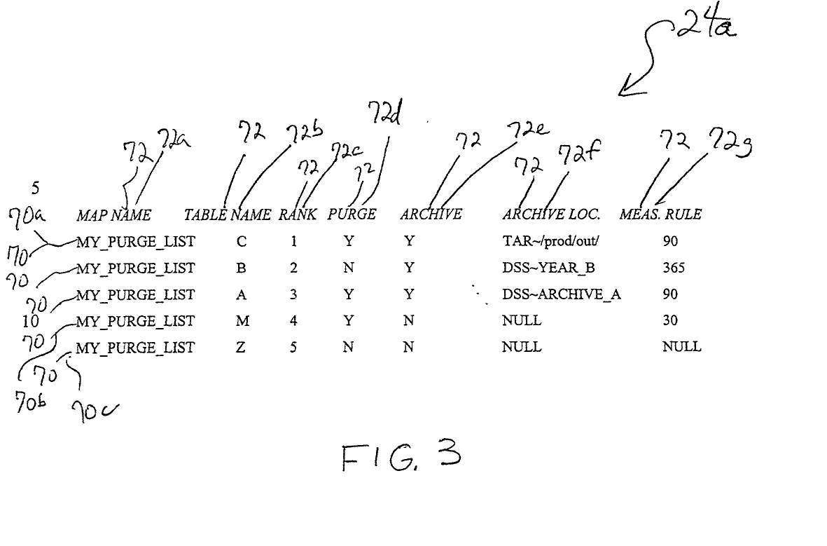

As an example, FIG. 3 depicts an exemplary mapping table 24a. As shown, the mapping table 24a includes columns 72 (columns 72a, 72b, 72c, 72d, 72e, 72f and 72g, as examples) and rows 70 (rows identified by 70a, 70b and 70c are referred to below in specific examples). Each row 70 is associated with a particular table 22. Each value in the column 72a designates a database or a set of tables, and each value in the column 72b designates a particular table to associate with the other values found in the row 70.

For example, the value at the intersection of column 72a and row 70a designates the tables associated with a database called MY_PURGE_LIST, and the value at the intersection of column 72b and row 70a designates a table called “C.” Therefore, the row 70a contains the rules that govern the purging and/or archiving of the rows of table C that is located in the MY_PURGE_LIST database. Likewise, as another example, the row 70b contains the rules that govern the purging and/or archiving of the rows of a table called “Z” that is located in the MY_PURGE_LIST database.

The column 72c is used to establish the order of table dependency by assigning each of the tables 22 that are contained in the mapping table 24 a relative priority. In this manner, each value in the column 72c designates a relative priority for the associated table 22. For example, for the row 70a, the value in the column 72c is a “1,” thereby designating table C as the table with the highest priority in the mapping table 24a. For the row 70b, the value in the column 72c is a “4,” thereby designating the table Z as having the fourth highest priority. Thus, giving the priorities shown in the exemplary mapping table 24a, the rows of table C are processed before the rows of table B, the rows of table B are processed before the rows of table A, etc.

The values in the column 72d are purge flags that indicate authorization to purge rows of the associated table if the measured properties of the rows meet the predefined measurement rule. Thus, as an example, the value at the intersection of column 72d and row 70a is a “Y” to indicate that the rows of table C are eligible for purging. As another example, the value at the intersection of column 72d and row 70c is an “N” to indicate that the rows of table Z are not eligible for purging.

The values in the column 72e are archive flags that indicate authorization to archive rows of the associated table if the measured properties of the rows meet the predefined measurement rule. The value at the intersection of column 72e and row 70a is a “Y” to indicate that the rows of table C are to be archived. As another example, the value at the intersection of column 72e and row 70c is an “N” to indicate that the rows of table Z are not to be archived.

Each value in the column 72f indicates the location to which the rows of the associated table 22 are to be archived. These locations may be other databases, zip drives or tape drives, as just few examples. It is noted that for tables M and Z that are not to be archived, a null value may be stored in the column 72f of the corresponding row 70.

Each value in the column 72g indicates the measurement rule to be applied to the associated table. The values in column 72g for the illustrated mapping table 24a indicate days to measure when operations are performed on the various tables. However, other rules that establish a limit on the size of the table or other criteria may be used.

Thus, as an example, the value at the intersection of column 72g and row 70a is “90” to indicate that purging (as indicated in column 72d) and archiving (as indicated in column 72e) should occur for rows (of table C) that are 90 or more days old. As another example, the value at the intersection of column 72g and row 70b is “30” to indicate that purging (as indicated in column 72d) should occur for the rows (of table M) that are 30 or more days old. It is noted that the value at the intersection of column 72g and row 70c is a null value, as no purging or archiving occurs for table Z.

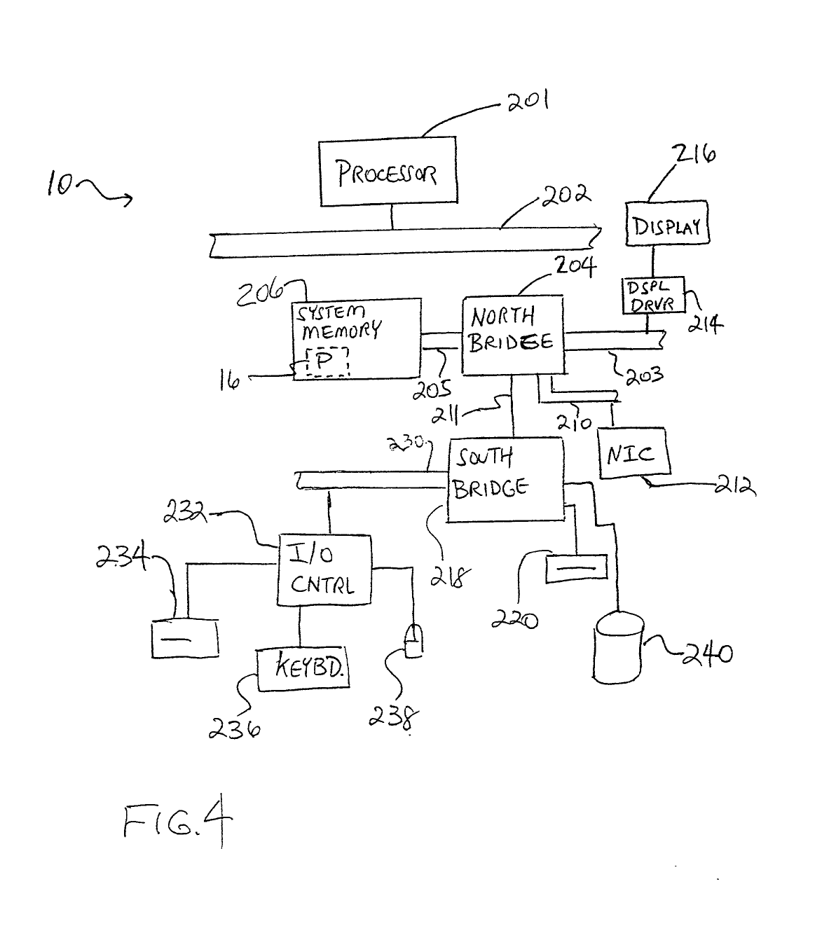

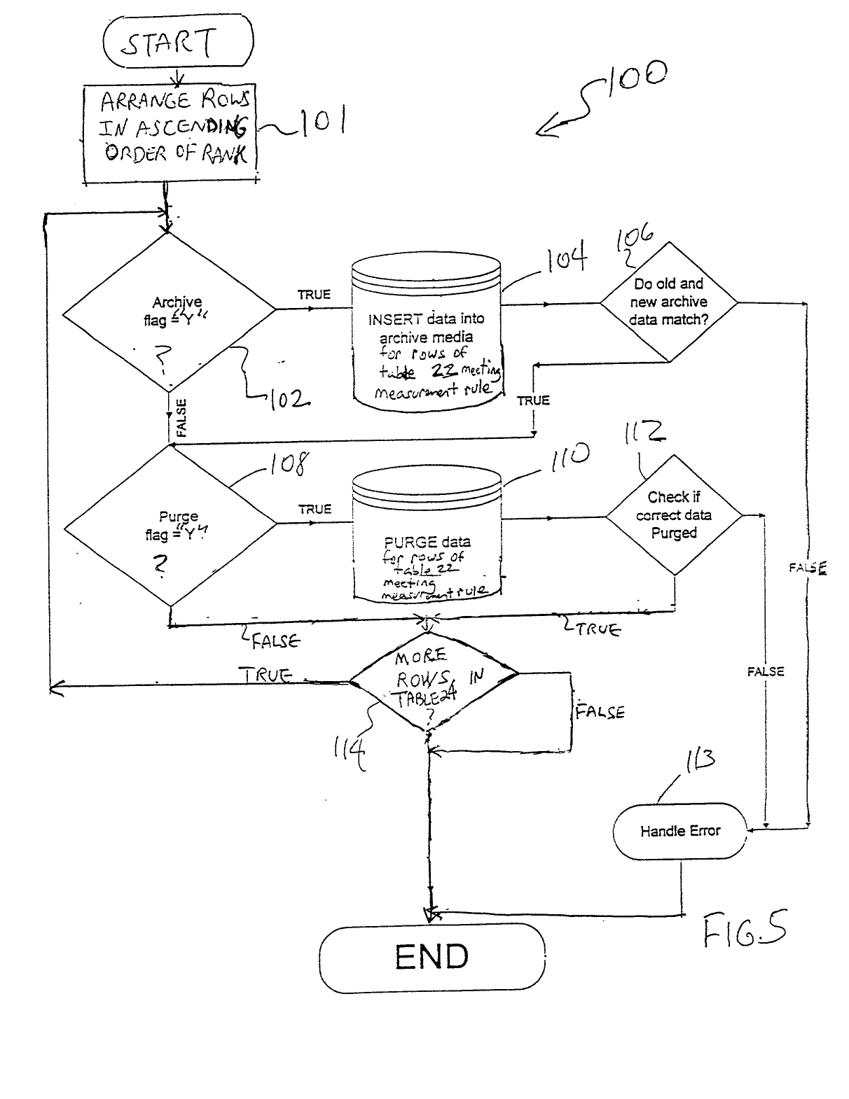

FIG. 4 depicts a possible hardware embodiment of the computer system 10. The computer system 10 may include at least one processor 201 that executes the operating system 12 (see also FIG. 1), the database management software 17 and the program 16. FIG. 5 depicts an exemplary routine 100 that may be performed by the processor 201 when executing the program 16, according to some embodiments of the invention.

In the routine, the processor 201 arranges (block 101) the rows of the mapping table 24 in ascending order so that the processor 201 processes the rows having the lowest rank (and therefore, the highest priority) in a manner that satisfies the locking ladder relationship (of the tables 22) that is described in the mapping table 24. After the rows of the mapping table 24 are ordered, the processor 201 processes the rows one at a time (in order) to determine which rows of the tables 22 need to be purged and/or archived.

In this manner, for each row of the mapping table 24, the processor 201 operates on the rows of the table 22 that is indicated by the currently processed row of the mapping table 24. For each row of the mapping table 24, the processor 201 determines if the associated archive flag is a “Y,” as depicted in diamond 102. If so, for the rows of the table 22 that meet the associated measurement rule (indicated by the currently processed row of the mapping table 24), the processor 201 copies the data from these rows of the table 22 and inserts this data into the associated archive media (also indicated by the currently processed row of the mapping table 24), as depicted in block 104. Next, the processor 201 determines (diamond 106) whether the archive data that was stored in the archive media matches the data (in the table 22) that was archived. If not, an error has occurred, and the processor 201 handles (block 113) the error and terminates the routine 100 to preserve the locking ladder order of the data.

If the processor 201 determines (diamond 106) that the two sets (original and archived) of data match, the processor 201 subsequently takes action to purge data from the table 22, based on the values in the currently processed row of the map table 24. In this manner, the processor 201 determines if the associated purge flag is a “Y,” as depicted in diamond 108. If so, for the rows of the table 22 that meet the associated measurement rule, the processor 201 purges these rows, as depicted in block 110. After purging, the processor 201 determines (diamond 112) whether the data was correctly purged. If not, an error has occurred, and the processor 201 handles (block 113) the error and terminates the routine 100.

After either the processor 201 successively finishes purging the data (if any) or not purging due to the purge flag being set to an “N,” the processor 201 determines (diamond 114) whether these are more rows in the mapping table 24 to process. If so, the processor 201 returns to diamond 102. Otherwise, the processor 201 terminates the routine 100.

Referring back to FIG. 4, in some embodiments of the invention, the processor 201 may be coupled to a local bus 202 along with a north bridge 204. The north bridge 204 may represent a collection of semiconductor devices, or “chip set,” and provide interfaces to a Peripheral Component Interconnect (PCI) bus 210 and an AGP bus 203. The PCI Specification is available from The PCI Special Interest Group, Portland, Ore. 97214. The AGP is described in detail in the Accelerated Graphics Port Interface Specification, Revision 1.0, published on Jul. 31, 1996, by Intel Corporation of Santa Clara, Calif..

A display driver 214 may be coupled to the AGP bus 203 and provide signals to drive a display 216. The PCI bus 210 may be coupled to a network interface card (NIC) 212 that provides a communication interface for the computer system 10 to the network 25 (see FIG. 1). The north bridge 204 may also include a memory controller to communicate data over a memory bus 205 with a memory 206. As an example, the memory 206 may store all or a portion of program instructions associated with the database management program 17 (see FIG. 1), the program 16, the network interface layer 11, and the operating system 12. In some embodiments of the invention, some of the above-described software may be executed on another computer system that is coupled to the computer system 10 via a network, such as the network 25.

The north bridge 204 communicates with a south bridge 218 via a hub link 211. The south bridge 218 may represent a collection of semiconductor devices, or “chip set,” and provide interfaces for a hard disk drive 240, a CD-ROM drive 220 and an I/O expansion bus 230, as just a few examples. The hard disk drive 240 may store all or a portion of the instructions of the database management program 17, the program 16, the network interface layer 11 and the operating system 12, in some embodiments of the invention.

An I/O controller 232 may be coupled to the I/O expansion bus 230 to receive input data from a mouse 238 and a keyboard 236. The I/O controller 232 may also control operations of a floppy disk drive 234.

While the invention has been disclosed with respect to a limited number of embodiments, those skilled in the art, having the benefit of this disclosure, will appreciate numerous modifications and variations therefrom. It is intended that the appended claims cover all such modifications and variations as fall within the true spirit and scope of the invention.

What is claimed is:

1. A method comprising:
providing a mapping table indicating different rules for archiving different database tables, each rule being associated with a different one of the tables; and
applying the rules to archive data from the different database tables.

2. The method of claim 1, wherein the database tables comprise relational database tables.

3. The method of claim 1, wherein the applying comprises:
for at least one of the database tables, measuring a property of each row of said at least one database table;
comparing the property to the associated rule; and
archiving based on the rule.

4. The method of claim 1, wherein the mapping table is arranged in rows and columns, each row being associated with one of the rules.

5. The method of claim 1, wherein at least one of the rules indicates a time of interval.

6. The method of claim 1, wherein at least one of the rules indicates a table size.

7. The method of claim 1, wherein the mapping table further indicates for each database table, authorization to purge data from the database table.

8. The method of claim 1, wherein the archiving comprises:
selectively archiving rows of the tables based on the rules.

9. The method of claim 1, wherein the mapping table further identifies locations for storing archived copies of the data.

10. A method comprising:
providing a mapping table indicating different rules for purging different database tables, each of the rules being associated with a different one of the database tables; and
applying the rules to purge data from the different database tables.

11. The method of claim 10, wherein the database tables comprise relational database tables.

12. The method of claim 10, wherein the applying comprises:
for at least one of the database tables, measuring a property of each row of said at least one database table;
comparing the property to the associated rule; and
purging based on the rule.

13. The method of claim 10, wherein the mapping table is arranged in rows and columns, each row being associated with one of the rules.

14. The method of claim 10, wherein at least one of the rules indicates a time interval.

15. The method of claim 10, wherein at least one of the rules indicates a table size.

16. The method of claim 10, wherein the mapping table further indicates for each database table, authorization to archive data from the database tables.

17. The method of claim 10, wherein the archiving comprises:
selectively archiving rows of the tables based on the rules.

18. The method of claim 10, wherein the mapping table further identifies locations for storing archived copies of the data.

19. A system comprising:
databases storing database tables and a mapping table, the mapping table indicating different rules for archiving the different database tables and each rule being associated with a different database table; and
a computer subsystem coupled to the databases to apply the rules to archived data from the different database tables.

20. The system of claim 19, wherein the database tables comprise relational database tables.

21. The system of claim 19, wherein the computer subsystem applies the rules by, for at least one of the database tables, measuring a property of each row of said at least one database table, comparing the property to the associated rule and archiving based on the rule.

22. The system of claim 19, wherein the mapping table is arranged in rows and columns, each row being associated with one of the rules.

23. The system of claim 19, wherein at least one of the rules indicate a time interval.

24. The system of claim 19, wherein at least one of the rules indicates a table size.

25. A system comprising:
databases storing database tables and a mapping table, the mapping table indicating different rules for purging the different database tables and each rule being associated with a different database table; and
a computer subsystem coupled to the databases to apply the rules to purge data from the different database tables.

26. The system of claim 25, wherein the database tables comprise relational database tables.

27. The system of claim 25, wherein the computer subsystem applies the rules by, for at least one of the database tables, measuring a property of each row of said at least one database table, comparing the property to the associated rule and purging based on the rule.

28. The system of claim 25, wherein the mapping table is arranged in rows and columns, each row being associated with one of the rules.

29. The system of claim 25, wherein at least one of the rules indicate a time interval.

30. The system of claim 25, wherein at least one of the rules indicates a table size.

31. An article comprising a computer readable storage medium storing instructions to cause a computer to:
access a mapping table that indicates different rules for archiving different database tables, each rule being associated with a different one of the tables, and
apply the rules to archive data from the different database tables.

32. The article of claim 31, wherein the database tables comprise relational database tables.

33. The article of claim 31, comprising instructions to cause the computer to for at least one of the database tables, measure a property of each row of said at least one database table, comparing the property to the associated rule and archive based on the rule.

34. The article of claim 31, wherein the mapping table is arranged in rows and columns, each row being associated with one of the rules.

35. An article comprising a computer readable storage medium storing instructions to cause a computer to:
access a mapping table that indicates different rules for purging different database tables, each rule being associated with a different one of the tables, and
apply the rules to purge data from the different database tables.

36. The article of claim 35, wherein the database tables comprise relational database tables.

37. The article of claim 35, comprising instructions to cause the computer to for at least one of the database tables, measure a property of each row of said at least one database table, comparing the property to the associated rule and purge based on the rule.

38. The article of claim 35, wherein the mapping table is arranged in rows and columns, each row being associated with one of the rules.
